(19) United States
(12) Patent Application Publication
(10) Pub. No.: US 2025/0220866 A1
(43) Pub. Date: Jul. 3, 2025

(54) ELECTROMAGNETIC LOSS FILM AND ELECTROMAGNETIC LOSS COMPOSITE STRUCTURE USING THE SAME

(71) Applicant: INDUSTRIAL TECHNOLOGY RESEARCH INSTITUTE, Hsinchu (TW)

(72) Inventors: Chun-Pin WU, Tainan City (TW); Shi-Yuan Tong, Hsinchu County (TW); Wen-Song Ko, Hsinchu City (TW)

(73) Assignee: INDUSTRIAL TECHNOLOGY RESEARCH INSTITUTE, Hsinchu (TW)

(21) Appl. No.: 18/641,582

(22) Filed: Apr. 22, 2024

(30) Foreign Application Priority Data
Dec. 29, 2023 (TW) 112151741

(51) Int. Cl. H05K 9/00

(52) U.S. Cl. CPC H05K 9/0088

(57) ABSTRACT

An electromagnetic loss film includes a magnetic oxide film body and a plurality of electromagnetic loss structures. The magnetic oxide film body corresponds to a magnetic response frequency (FR), and the range of the magnetic response frequency is 0.1 MHz≤FR≤300 GHz. The electromagnetic loss structures are formed in the magnetic oxide film body, and the electromagnetic loss structures penetrate or are recessed in the magnetic oxide film body. Each of the electromagnetic loss structures has a long diameter, and the long diameter is N1x light velocity/FR, and 0.005≤N1≤1, and a space between the electromagnetic loss structures is N2x light velocity/FR, wherein 0.005≤N2≤1, and N1<N2.

### CROSS-REFERENCE TO RELATED APPLICATION

This non-provisional application claims priority under 35 U.S.C. § 119(a) to patent application No. 112151741 filed in Taiwan, R.O.C. on Dec. 29, 2023, the entire contents of which are hereby incorporated by reference.

### TECHNICAL FIELD

The present disclosure relates to the field of electromagnetic shielding, and in particular, to an electromagnetic loss film and an electromagnetic loss composite structure using the same.

### BACKGROUND

With the advancement of communication technology, the installation density of electronic components is gradually increasing, but it also produces many side effects. The new generation of communication technology, ultra-high frequency and multi-functional communication band systems, has shortened the distance between modules, resulting in a significant increase in interactive electromagnetic interference (EMI), and causing a decrease in system performance and the loss of the advantages of low delay and high reliability of signal transmission.

A common method in the art is to coat the surface of the module with a metal layer, and use the metal to reflect electromagnetic waves to achieve the effect of inhibiting EMI interference. However, the electromagnetic waves reflected in this method will form a secondary EMI source, affecting surrounding components. The electromagnetic wave noise generated between internal components will be reflected by the metal layer, causing EMI, affecting module operation performance and reducing communication quality.

### SUMMARY

The present disclosure discloses an electromagnetic loss film. The electromagnetic loss film according to an embodiment includes a magnetic oxide film body and a plurality of electromagnetic loss structures. The magnetic oxide film body corresponds to a magnetic response frequency (FR), and the range of the magnetic response frequency is 0.1 MHz≤FR≤300 GHz. The electromagnetic loss structures are formed in the magnetic oxide film body, and the electromagnetic loss structures penetrate or are recessed in the magnetic oxide film body. Each of the electromagnetic loss structures has a long diameter, and the long diameter is N1x light velocity/FR, and 0.005≤N1≤1; and a space between the electromagnetic loss structures is N2x light velocity/FR, 0.005≤N2≤1, and N1<N2.

Further, in some embodiments, the present disclosure further provides an electromagnetic loss composite structure. The electromagnetic loss composite structure includes a first electromagnetic loss film and a second electromagnetic loss film. The second electromagnetic loss film is positioned on the first electromagnetic loss film. The first electromagnetic loss film and the second electromagnetic loss film respectively include a magnetic oxide film body and a plurality of electromagnetic loss structures. A magnetic oxide film body corresponds to a magnetic response frequency (FR), and the range of the magnetic response frequency is 0.1 MHz≤FR≤300 GHz. The electromagnetic loss structures penetrate or are recessed in the magnetic oxide film body, and each of the electromagnetic loss structures has a long diameter; the long diameter is N1x light velocity/FR, and 0.005≤N1≤1; and a space between the electromagnetic loss structures is N2x light velocity/FR, 0.005≤N2≤1, and N1<N2.

### BRIEF DESCRIPTION OF THE DRAWINGS

The present disclosure can be more fully understood by reading the subsequent detailed description and examples with references made to the accompanying drawings, wherein:

FIG. 1 is a schematic diagram of Embodiment 1 of an electromagnetic loss film.

FIG. 2 is a schematic diagram of Embodiment 2 of an electromagnetic loss film.

FIG. 3 is a schematic diagram of Embodiment 3 of an electromagnetic loss film.

FIG. 4 is a schematic diagram of Embodiment 4 of an electromagnetic loss film.

FIG. 5A is a schematic diagram of Embodiment 5 of an electromagnetic loss film.

FIG. 5B is a sectional diagram of Embodiment 5 of an electromagnetic loss film.

FIG. 6 is a schematic diagram of Embodiment 6 of an electromagnetic loss film.

FIG. 7 is a schematic diagram of Embodiment 7 of an electromagnetic loss film.

FIG. 8 is a schematic diagram of Embodiment 8 of an electromagnetic loss film.

FIG. 9 is a schematic diagram of Embodiment 9 of an electromagnetic loss film.

FIG. 10 is a schematic diagram of Embodiment 1 of an electromagnetic loss composite structure.

FIG. 11 is a schematic diagram of Embodiment 2 of an electromagnetic loss composite structure.

FIG. 12 is a schematic diagram of Embodiment 3 of an electromagnetic loss composite structure.

FIG. 13A to FIG. 13D are wave frequency diagrams of frequency-attenuation degrees of electromagnetic loss films with different electromagnetic loss structure shapes.

FIG. 14A and FIG. 14B are wave frequency diagrams of frequency-attenuation degree of an electromagnetic loss film at a low magnetic response frequency.

FIG. 15A to FIG. 15G, and FIG. 16A to FIG. 16D are wave frequency diagrams of frequency-attenuation degree of an electromagnetic loss film at different magnetic response frequencies.

FIG. 17 is a wave frequency diagram of frequency-attenuation degree under different N1/N2 ratios.

FIG. 18 is a wave frequency diagram of frequency-attenuation degrees of electromagnetic loss films with different thicknesses.

FIG. 19 is a wave frequency diagram of frequency-attenuation degrees of electromagnetic loss composite structures with different aperture ratios.

FIG. 20 is a wave frequency diagram of frequency-attenuation degree in an actual product.

### DETAILED DESCRIPTION

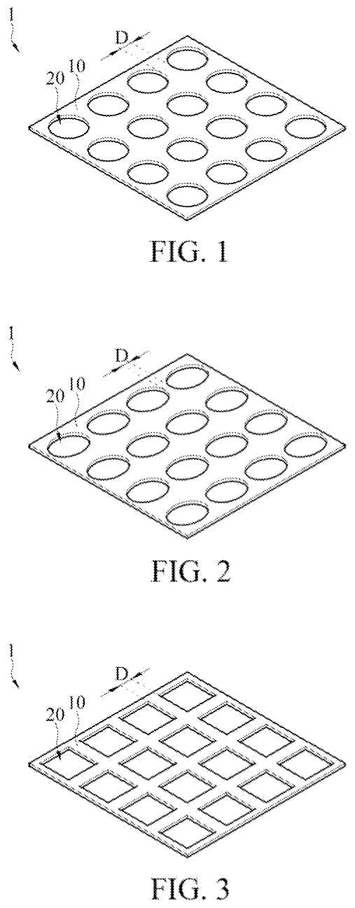

FIG. 1 is a schematic diagram of Embodiment 1 of an electromagnetic loss film. As shown in FIG. 1, an electromagnetic loss film 1 includes a magnetic oxide film body 10 and a plurality of electromagnetic loss structures 20. The magnetic oxide film body 10 corresponds to a magnetic response frequency (FR), and the range of the magnetic response frequency is 0.1 MHz≤FR≤300 GHz. The electromagnetic loss structures 20 are formed in the magnetic oxide film body 10. In Embodiment 1, the electromagnetic loss structures 20 are circular through holes that penetrate the magnetic oxide film body 10. The diameter of each of the electromagnetic loss structures 20 is N1x light velocity/FR, and 0.005≤N1≤1. A space D between the electromagnetic loss structures 20 is N2x light velocity/FR, 0.005≤N2≤1, and N1<N2.

The magnetic oxide film body 10 is made of iron oxide, cobalt oxide, nickel oxide, manganese oxide, and iron, cobalt, nickel and manganese alloy oxides. The electromagnetic loss film 1 is mainly used for being attached to the outside of an electronic component for packaging and shielding. Electromagnetic waves generated inside can be concentrated into the electromagnetic loss structures 20 and consumed through reflection and absorption. Therefore, the magnetic response frequency (FR) may be selected according to the frequency mainly generated by the electronic component, and then a proper magnetic oxide material ratio is selected. Further, the magnetic oxide film body 10 can be doped with conductive magnetic consumables and dielectric magnetic consumables to achieve a better electromagnetic loss function. More specifically, the dielectric magnetic consumables may be titanium oxide, barium oxide or titanium-barium alloy oxide; and the conductive magnetic consumables may be gold, silver, aluminum, iron, cobalt, nickel, manganese, carbon and graphite, and may be doped in the magnetic oxide film body 10 in a powder mode.

FIG. 2 is a schematic diagram of Embodiment 2 of an electromagnetic loss film. FIG. 3 is a schematic diagram of Embodiment 3 of an electromagnetic loss film. As shown in FIG. 2 and FIG. 3, and referring to FIG. 1, different from Embodiment 1, the electromagnetic loss structures 20 in FIG. 2 are elliptic through holes, and the electromagnetic loss structures 20 in FIG. 3 are rectangular through holes. Generally, the long axis of an ellipse, the side length of a rectangle and the diameter of a circle are collectively called long diameters. The length of the long diameter corresponds to N1x light velocity/FR, and 0.005≤N1≤1. Further, there is a relation of 0.1≤N1/N2<1.

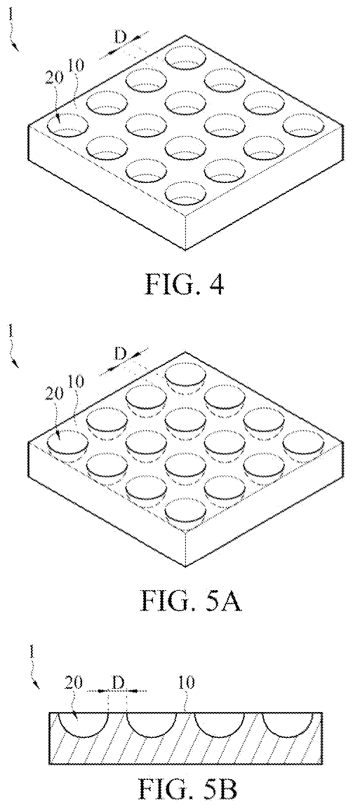

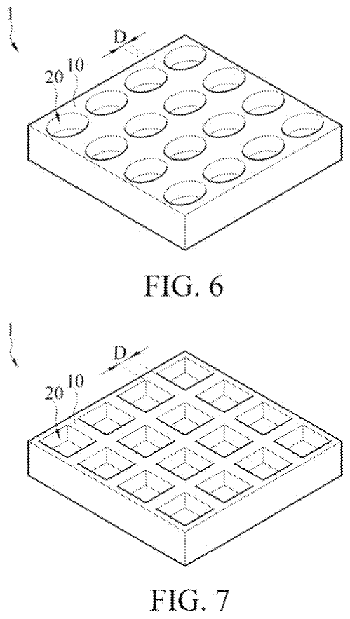

FIG. 4 is a schematic diagram of Embodiment 4 of an electromagnetic loss film. FIG. 5A is a schematic diagram of Embodiment 5 of an electromagnetic loss film. FIG. 5B is a sectional diagram of Embodiment 5 of an electromagnetic loss film. FIG. 6 is a schematic diagram of Embodiment 6 of an electromagnetic loss film. FIG. 7 is a schematic diagram of Embodiment 7 of an electromagnetic loss film. As shown in FIG. 4 to FIG. 7, and referring to FIG. 1 to FIG. 3, the difference between Embodiment 4 to Embodiment 7 and the previous embodiments is that the electromagnetic loss structures 20 are blind holes recessed in the magnetic oxide film body 10, but the electromagnetic loss structures may be of different shapes, such as cylindrical blind holes, hemispherical blind holes, semi-elliptic cylindrical blind holes or square cylindrical blind holes. The magnetic oxide film body 10 is not specially limited in thickness, and may has different thicknesses mainly according to product requirements, and the thickness range may be 0.1 mm to 25 m, such as 0.2 mm to 25 mm, 0.25 mm to 8 mm, 25 mm to 100 mm, 100 mm to 1 m, and 1 m to 25 m.

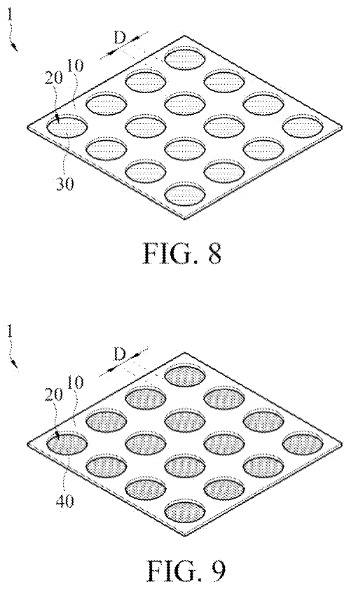

FIG. 8 is a schematic diagram of Embodiment 8 of an electromagnetic loss film. As shown in FIG. 8, and referring to FIG. 1, in Embodiment 8, an adhesive film layer 30 is attached to the surface of the magnetic oxide film body 10. The adhesive film layer 30 further improves the absorption effect on electromagnetic waves in the electromagnetic loss structures 20. The adhesive film layer 30 can also be applied to the electromagnetic loss film 1 in Embodiment 2 to Embodiment 6.

FIG. 9 is a schematic diagram of Embodiment 9 of an electromagnetic loss film. As shown in FIG. 9, and referring to FIG. 1, in Embodiment 9, a metal layer 40 is attached to the surface of the magnetic oxide film body 10. The metal layer 40 reflects external electromagnetic waves. Electromagnetic waves generated by an internal component can be concentrated in the electromagnetic loss structures 20 to be lost. The metal layer 40 can also be applied to the electromagnetic loss film 1 in Embodiment 2 to Embodiment 7.

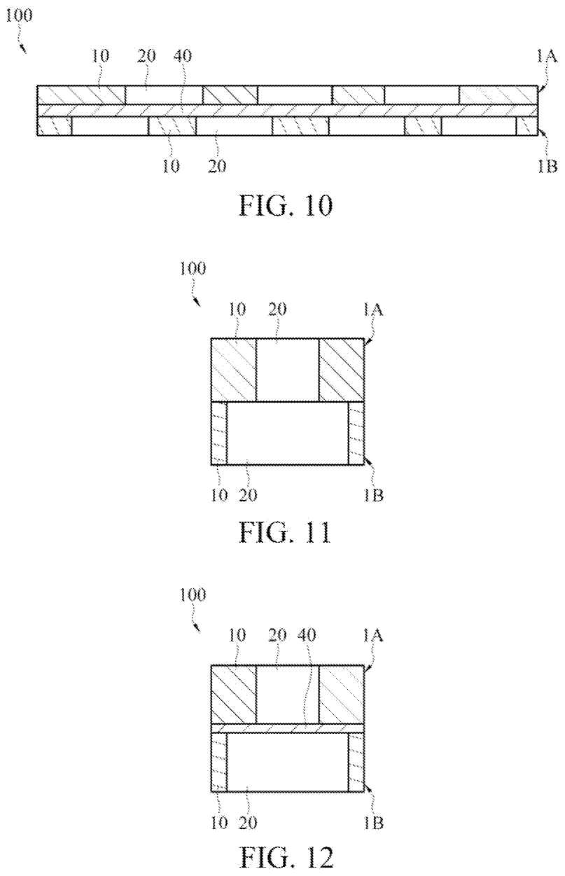

FIG. 10 is a schematic diagram of Embodiment 1 of an electromagnetic loss composite structure. As shown in FIG. 10, an electromagnetic loss composite structure 100 includes a first electromagnetic loss film 1A and a second electromagnetic loss film 1B. The second electromagnetic loss film 1B is positioned on the first electromagnetic loss film 1A. The electromagnetic loss composite structure 100 may be combined by various embodiments shown in FIG. 1 to FIG. 7. The first electromagnetic loss film 1A and the second electromagnetic loss film 1B are the same as the abovementioned electromagnetic loss film 1. However, magnetic oxide film bodies 10 corresponding to the same magnetic response frequency or different magnetic response frequencies may be selected according to actual requirements. Therefore, adjustment may be performed for different wave frequency environments and products. In addition, when the magnetic oxide film bodies 10 with the same magnetic response frequency are selected, electromagnetic loss structures 20 having different shapes or spaces D may be selected.

Further, in some embodiments, the electromagnetic loss composite structure 100 further includes the metal layer 40, and the metal layer 40 is positioned between the first electromagnetic loss film 1A and the second electromagnetic loss film 1B. That is, embodiment shown in FIG. 9 may be combined with embodiments in FIG. 1 to FIG. 7.

FIG. 11 is a schematic diagram of Embodiment 2 of an electromagnetic loss composite structure. FIG. 12 is a schematic diagram of Embodiment 3 of an electromagnetic loss composite structure. As shown in FIG. 11 and FIG. 12, and referring to FIG. 10, in Embodiment 2 and Embodiment 3 of the electromagnetic loss composite structure, the electromagnetic loss structures 20 of the first electromagnetic loss film 1A and the second electromagnetic loss film 1B are different in long diameter. That is, the most suitable solution may be selected according to the frequency generated by the electronic component and the external wave frequency environment through double-layer matching and by considering whether the metal layer 40 is applied or not, and thus the interference of external electromagnetic waves can be isolated; and meanwhile, the electromagnetic wave interference generated by the internal electronic component can be avoided.

In the electromagnetic loss composite structure 100, if the electromagnetic loss structures 20 of the first electromagnetic loss film 1A and the second electromagnetic loss film 1B are different in long diameter, the larger long diameter is defined as R, the smaller long diameter is defined as R1, R is N1x light velocity/FR, and 0.005≤N1≤1. A space D between the electromagnetic loss structures 20 is N2x light velocity/FR, 0.005≤N2≤1, and N1<N2. In addition, R1 is N1xN3x light velocity/FR, and 0.1≤N3≤1.

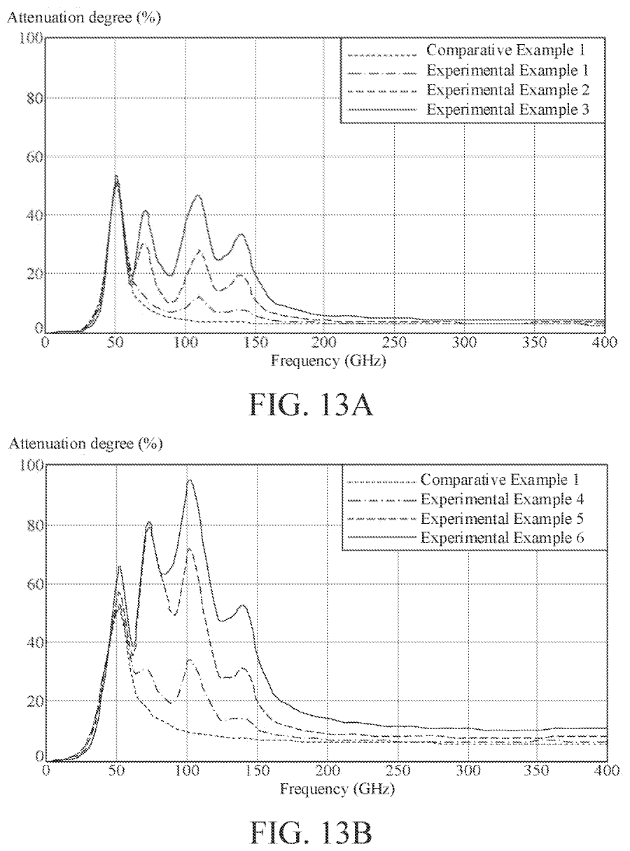

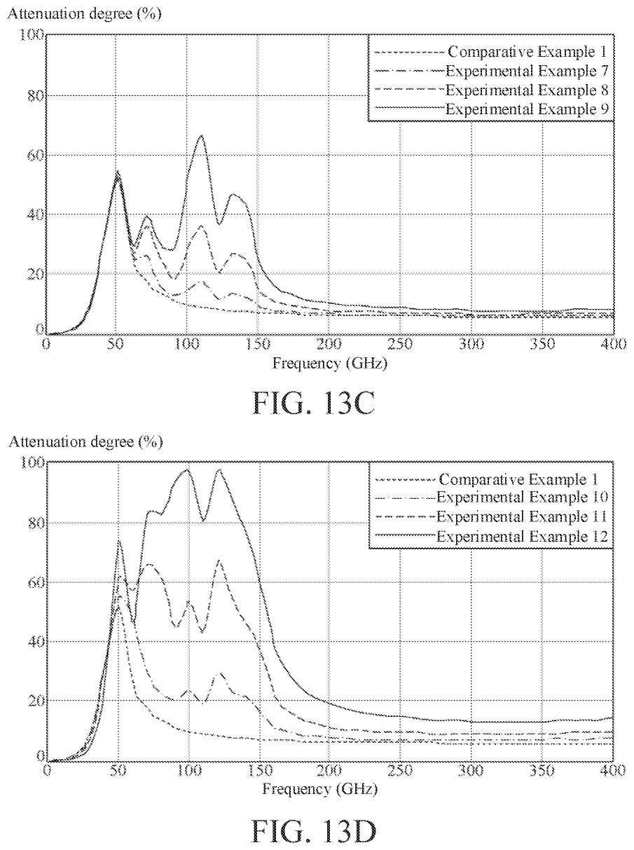

The actual experimental efficacy will be described in the following according to the wave frequency diagrams of frequency-attenuation degrees of different embodiments. FIG. 13A to FIG. 13D are wave frequency diagrams of frequency-attenuation degrees of electromagnetic loss films with different electromagnetic loss structure shapes. The magnetic oxide film body 10 corresponding to magnetic response frequency of 50 GHz is selected, and the thickness of the magnetic oxide film body 10 is 0.25 mm. According to the condition that the space D between the electromagnetic loss structures 20 is N2x light velocity/FR, and 0.005≤N2≤1, selecting N2 as 0.23, 0.12 and 0.08 to reversely deduce the space is treated as Experimental Embodiment 1, Experimental Embodiment 2, Experimental Embodiment 3, . . . , Experimental Embodiment 10, Experimental Embodiment 11, and Experimental Embodiment 12. The magnetic oxide film body 10 without holes is treated as Comparative Embodiment 1. The structure in Embodiment 4 is adopted in FIG. 13A; in FIG. 13B, Embodiment 4 is matched with the metal layer in FIG. 9; the structure in Embodiment 5 is adopted in FIG. 13C; and the structure in Embodiment 7 is adopted in FIG. 13D.

No matter what structure of the electromagnetic loss film 1 is used, it may be found that full-width at half maximum at the absorption peak of 50 GHz is slightly increased. In addition, the absorption peak is generated in other frequency ranges. Therefore, through absorption of a plurality of frequency bands, electromagnetic waves can be effectively consumed and attenuated as a whole.

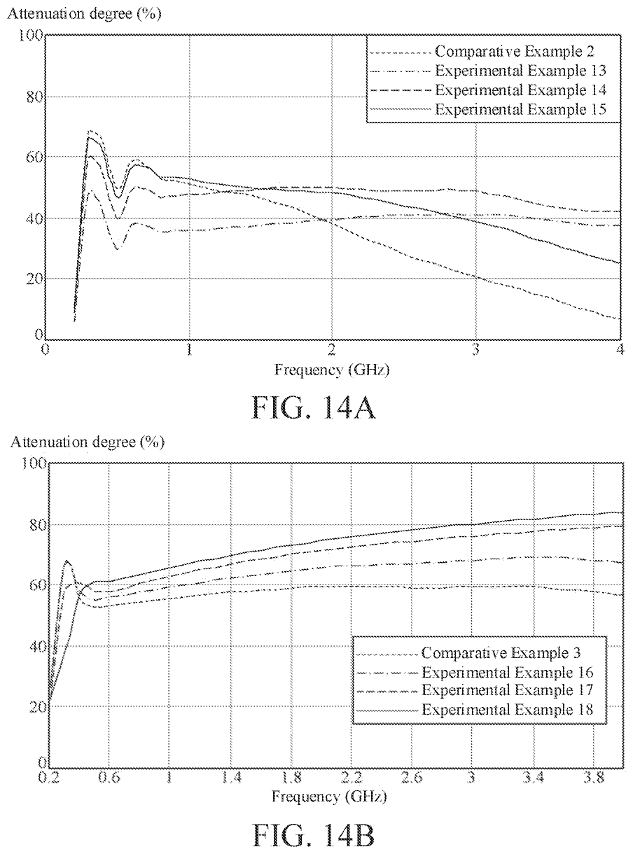

FIG. 14A and FIG. 14B are wave frequency diagrams of frequency-attenuation degree of an electromagnetic loss film at a low magnetic response frequency. As shown in FIG. 14A and FIG. 14B, the structure in Embodiment 4 is adopted, and 0.3 MHz and 0.3 GHz are selected as the magnetic response frequency. According to the condition that the space D between the electromagnetic loss structures 20 is N2x light velocity/FR, and 0.005≤N2≤1, selecting N2 as 0.07, 0.04 and 0.02 to reversely deduce the space D is treated as Experimental Embodiment 13, Experimental Embodiment 14, Experimental Embodiment 15, Experimental Embodiment 16, Experimental Embodiment 17 and Experimental Embodiment 18. The magnetic oxide film body 10 without the holes is treated as Comparative Embodiment 2 and Comparative Embodiment 3 for comparison. Due to the low frequency, the thickness of the magnetic oxide film body 10 is large and is 25 m and 25 mm separately. The electromagnetic loss film is mostly applied to frequency absorption of military affairs, space and mansions.

As shown in FIG. 14A and FIG. 14B, the phenomenon that the full-width at half maximum at the corresponding absorption peak is slightly increased can be found, and the overall attenuation degree is improved.

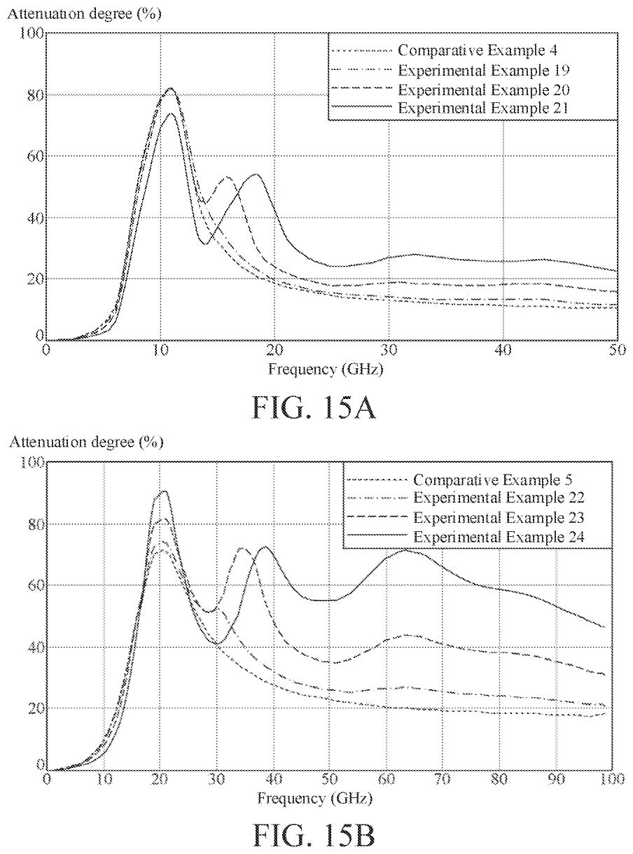

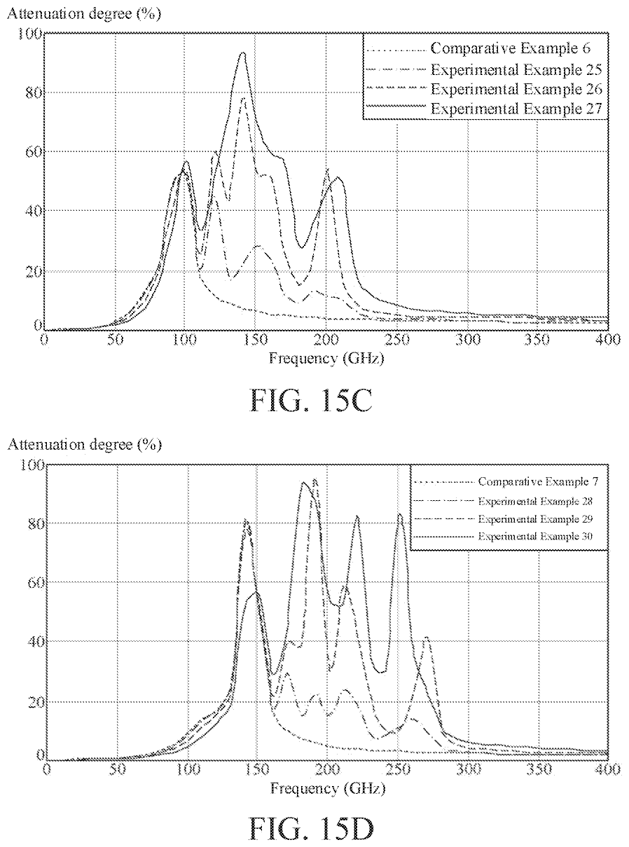

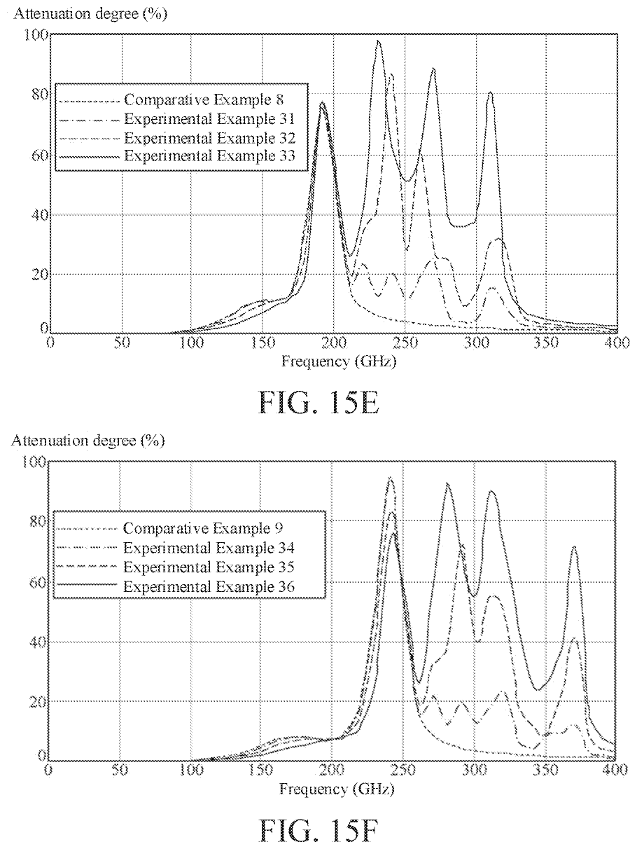

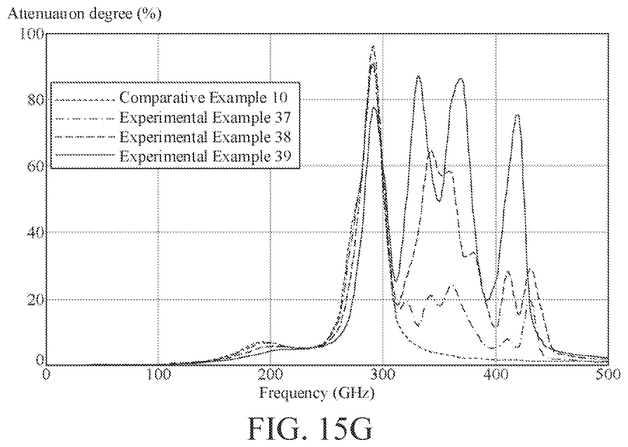

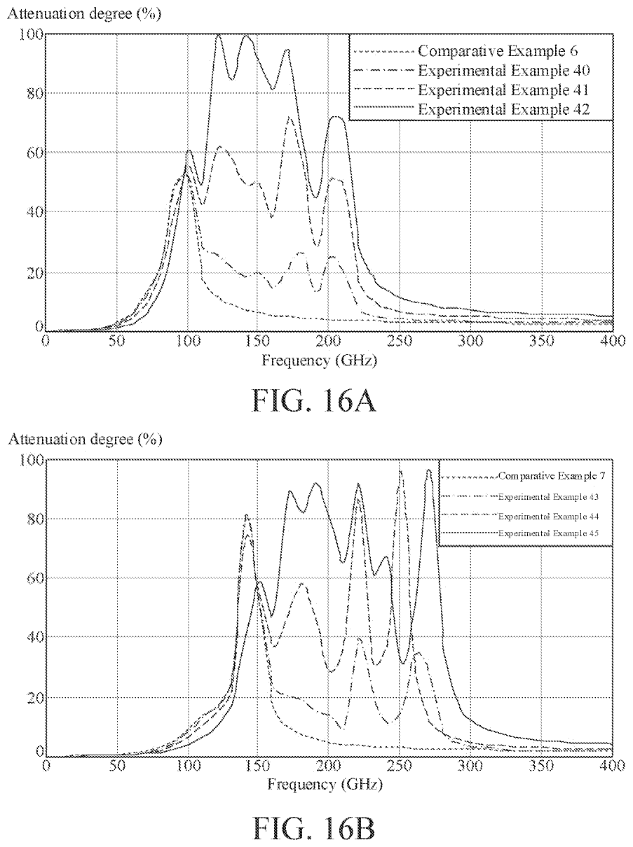

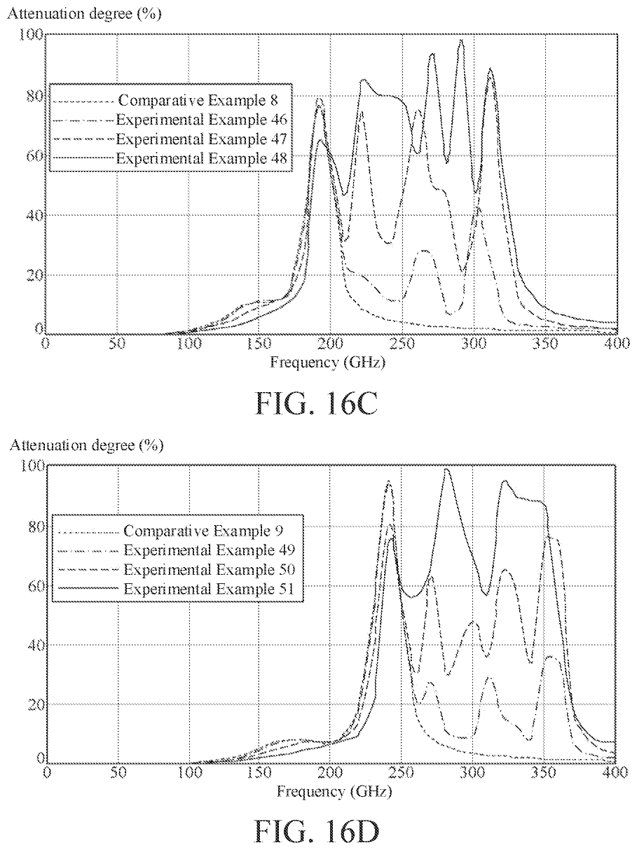

FIG. 15A to FIG. 15G, and FIG. 16A to FIG. 16D are wave frequency diagrams of frequency-attenuation degree of an electromagnetic loss film at different magnetic response frequencies. The thickness of the magnetic oxide film bodies 10 in FIG. 15A to FIG. 16D is 0.25 mm. The structure in Embodiment 4 is adopted in FIG. 15A to FIG. 15G, and the selected magnetic response frequencies are 10 GHz, 20 GHz, 100 GHz, 150 GHz, 200 GHz, 250 GHz and 300 GHz respectively. According to the condition that the space D between the electromagnetic loss structures 20 is N2x light velocity/FR, and 0.005≤N2≤1, selecting N2 as 0.23, 0.12 and 0.08 to reversely deduce the space D is treated as Experimental Embodiment 19, Experimental Embodiment 20, an Experimental Embodiment 21, . . . , Experimental Embodiment 37, Experimental Embodiment 38 and Experimental Embodiment 39. The magnetic oxide film body 10 without the holes is treated as Comparative Embodiment 4, Comparative Embodiment 5, Comparative Embodiment 6, Comparative Embodiment 7, Comparative Embodiment 8, Comparative Embodiment 9 and Comparative Embodiment 10 for comparison.

The structure in Embodiment 7 is adopted in FIG. 16A to FIG. 16D, and the selected magnetic response frequencies are 100 GHz, 150 GHz, 200 GHz and 250 GHz respectively. According to the condition that the space D between the electromagnetic loss structures 20 is N2x light velocity/FR, and 0.005≤N2≤1, selecting N2 as 0.23, 0.12 and 0.08 to reversely deduce the space D is treated as Experimental Embodiment 40, Experimental Embodiment 41, Experimental Embodiment 42, . . . , an Experimental Embodiment 49, Experimental Embodiment 50 and Experimental Embodiment 51. The Comparative Embodiment 6, Comparative Embodiment 7, Comparative Embodiment 8 and Comparative Embodiment 9 are matched respectively for comparison.

As shown in FIG. 15A to FIG. 16D, compared with the comparative embodiments, the electromagnetic loss structures 20 are arranged, so the range corresponding to magnetic response absorption peak absorption may be expanded, and the peak value is increased. Further, under different space conditions, more absorption peak values may be generated. Therefore, the frequency band range of absorbing the electromagnetic waves can be effectively expanded through the electromagnetic loss structures 20. Therefore, the electromagnetic loss structures 20 are beneficial to absorbing the electromagnetic waves, attenuating the intensity of the electromagnetic waves, and particularly absorbing electromagnetic waves generated by the internal electronic component.

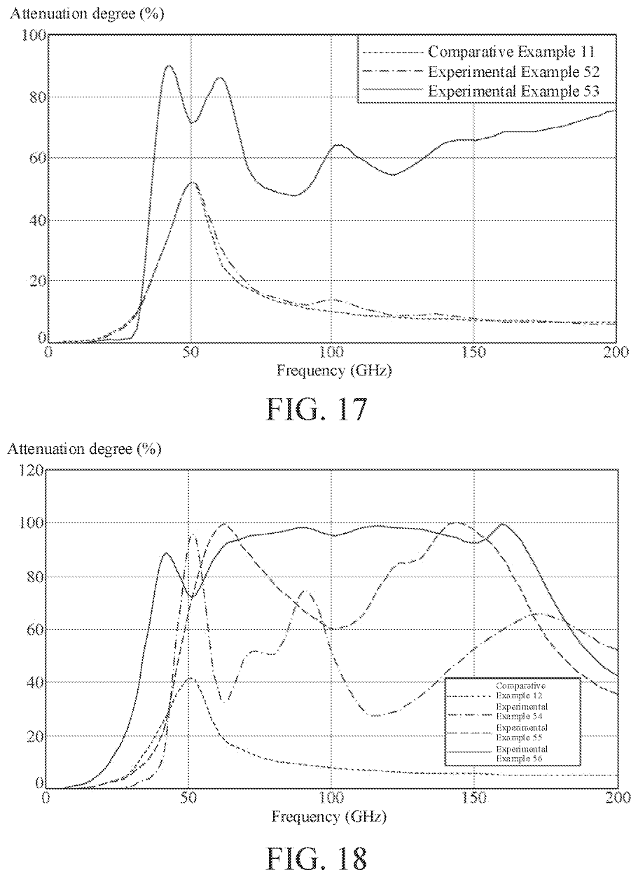

FIG. 17 is a wave frequency diagram of frequency-attenuation degree under different N1/N2 ratios. The structure in Embodiment 1 is adopted in FIG. 17, and the selected magnetic response frequency is 50 GHz. The fixed space D between two electromagnetic loss structures 20 is 5.996 mm. The magnetic oxide film body 10 with the thickness of 0.25 is adopted. The N1/N2 ratios in Experimental Embodiment 52 and Experimental Embodiment 53 are 0.1 and 0.9 respectively. The magnetic oxide film body 10 without the holes is treated as Comparative Embodiment 11 for comparison.

As shown in FIG. 17, in the experimental embodiments under different N1/N2 ratios, the absorbance and frequency range both can be improved, for embodiment, the absorption characteristic under 0.1≤N1/N2<1 is good. Experimental Embodiment 53 is more obvious in generating other absorption peak values.

FIG. 18 is a wave frequency diagram of frequency-attenuation degrees of electromagnetic loss films with different thicknesses. The structure in Embodiment 1 is adopted in FIG. 18, and the selected magnetic response frequency is 50 GHz. According to the condition that N1 is 0.009, and N2 is 0.01, the magnetic oxide film bodies 10 with the thicknesses of 0.2 mm, 1 mm and 8 mm are selected as Experimental Embodiment 54, Experimental Embodiment 55 and Experimental Embodiment 56. The magnetic oxide film body 10 with the thickness of 0.2 mm and without the holes is selected as Comparative Embodiment 12.

As shown in FIG. 18, no matter what thickness is, the electromagnetic loss film 1 with the electromagnetic loss structures 20 can achieve the effect of increasing the frequency range of magnetic response absorption peak absorption and has more characteristics of absorption peak generation.

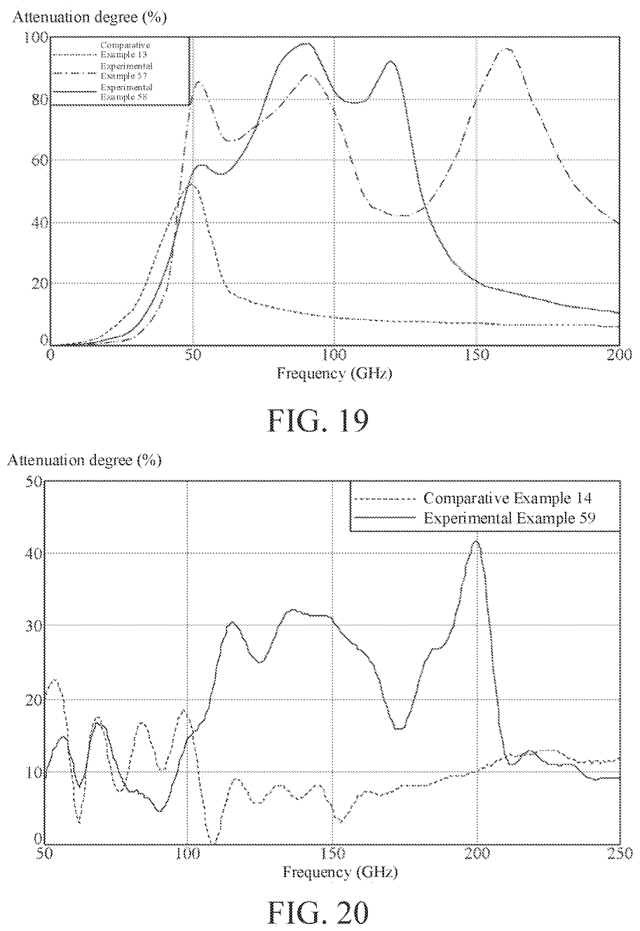

FIG. 19 is a wave frequency diagram of frequency-attenuation degrees of electromagnetic loss composite structures with different aperture ratios. As shown in FIG. 19, the structure in Embodiment 2 of the electromagnetic loss composite structure is adopted in FIG. 19, and the selected magnetic response frequency is 50 GHz. The magnetic oxide film body 10 with the double-layer thickness of 0.25 mm is adopted, N1 is 0.05, and N3 is 0.9 and 0.5 in Experimental Embodiment 57 and Experimental Embodiment 58. Different aperture ratios are provided, and a 0.5 mm magnetic oxide film body 10 without the holes is selected in Comparative Embodiment 13.

As shown in FIG. 19, Experimental Embodiment 57 and Experimental Embodiment 58 both show that the electromagnetic loss film 1 with the electromagnetic loss structures 20 can achieve the effect of increasing the range of magnetic response absorption peak absorption and has more characteristics of absorption peak generation.

FIG. 20 is a wave frequency diagram of frequency-attenuation degree in an actual product. As shown in FIG. 20, the electromagnetic loss film 1 in Experimental Embodiment 59 adopts the structure in Embodiment 3, and the selected magnetic response frequency is 50 GHz. The magnetic oxide film body 10, having the thickness of 0.15 mm, having a square opening, and having the side length of 0.29 mm, and the hole space D of 0.49 mm, is coated on a product to serve as a sample, such as a chip, an electronic component, an antenna, a RADAR, a printed circuit board, related parts, and buildings, but not limited to the above. Meanwhile, the magnetic oxide film body 10 with the thickness of 0.15 mm and without the opening is treated as Comparative Embodiment 14 for comparison. As for the measurement mode, a system (a TeraFlash pro system of Toptica Company, adopting a THz time-domain spectroscopy (TDS)) of the electronic product for measuring the wave frequency is particularly used for measuring the attenuation degree characteristic of the sample.

As shown in FIG. 20, in addition to the absorption characteristic of 50 GHz, a good absorption effect is especially achieved at 60-250 GHz.

In the experiment of the inventors, the electromagnetic loss film 1 with the electromagnetic loss structures 20 has a better effect than the electromagnetic loss film without the electromagnetic loss structures 20 in different embodiments. For magnetic response frequency ranges of different electronic apparatuses or large devices, the frequency bands commonly selected are 3 MHz to 0.03 GHz, 0.03 GHz to 0.3 GHz, 0.3 GHz to 1 GHz, 1 GHz to 2 GHz, 2 GHz to 4 GHz, 4 GHz to 8 GHz, 8 GHz to 12 GHz, 12 GHz to 18 GHz, 18 GHz to 27 GHz, 27 GHz to 40 GHz, 40 GHz to 75 GHz, 75 GHz to 110 GHz, 110 GHz to 300 GHz, and the like.

In conclusion, in some embodiments, by forming the electromagnetic loss structures 20 on the magnetic oxide film body 10, absorption peaks of other frequency bands can be generated in addition to the magnetic response absorption peak value, so that the absorption frequency band of electromagnetic waves is expanded, and the practicability is greatly improved. When the magnetic response frequency is properly selected, electromagnetic wave interference can be effectively avoided, and then the problems in the prior art are solved.

Although the present disclosure has been described in considerable detail with reference to certain embodiments thereof, the disclosure is not for limiting the scope of the disclosure. Persons having ordinary skill in the art may make various modifications and changes without departing from the scope and spirit of the disclosure. Therefore, the scope of the appended claims should not be limited to the description of the preferred embodiments described above.

What is claimed is:

1. An electromagnetic loss film, comprising:
a magnetic oxide film body which corresponds to a magnetic response frequency (FR), wherein a range of the magnetic response frequency is 0.1 MHz≤FR≤300 GHz; and
a plurality of electromagnetic loss structures formed in the magnetic oxide film body, wherein the electromagnetic loss structures penetrate or are recessed in the magnetic oxide film body, and each of the electromagnetic loss structures has a long diameter;
wherein the long diameter is N1x light velocity/FR, and 0.005≤N1≤1; and a space between the electromagnetic loss structures is N2x light velocity/FR, wherein 0.005≤N2≤1, and N1<N2.

2. The electromagnetic loss film according to claim 1, wherein the long diameter of the electromagnetic loss structures and the space between the electromagnetic loss structures have a relation of 0.1≤N1/N2<1.

3. The electromagnetic loss film according to claim 1, wherein each of the electromagnetic loss structures is a hole penetrating through the magnetic oxide film body or a blind hole accessed in the magnetic oxide film body.

4. The electromagnetic loss film according to claim 3, wherein the hole is circular, elliptic or rectangular.

5. The electromagnetic loss film according to claim 3, wherein the blind hole is a cylindrical blind hole, a hemispherical blind hole, a semi-elliptical cylindrical blind hole or a square cylindrical blind hole.

6. The electromagnetic loss film according to claim 1, wherein the magnetic oxide film body is selected from a group consisting of iron oxide, cobalt oxide, nickel oxide, manganese oxide, and iron, cobalt, nickel and manganese alloy oxides.

7. The electromagnetic loss film according to claim 1, further comprising an adhesive film layer, wherein the adhesive film layer is attached to a surface of the magnetic oxide film body.

8. The electromagnetic loss film according to claim 1, further comprising a metal layer, wherein the metal layer is attached to a surface of the magnetic oxide film body.

9. An electromagnetic loss composite structure, comprising:
a first electromagnetic loss film; and
a second electromagnetic loss film which is positioned on the first electromagnetic loss film;
wherein the first electromagnetic loss film and the second electromagnetic loss film respectively comprise a magnetic oxide film body and a plurality of electromagnetic loss structures; the magnetic oxide film body corresponds to a magnetic response frequency (FR), and the range of the magnetic response frequency is 0.1 MHz≤FR≤300 GHz; the electromagnetic loss structures penetrate or are recessed in the magnetic oxide film body; each of the electromagnetic loss structures has a long diameter, the long diameter is N1x light velocity/FR, and 0.005≤N1≤1; and a space between the electromagnetic loss structures is N2x light velocity/FR, where 0.005≤N2≤1, and N1<N2.

10. The electromagnetic loss composite structure according to claim 9, further comprising a metal layer, wherein the metal layer is positioned between the first electromagnetic loss film and the second electromagnetic loss film.

11. The electromagnetic loss composite structure according to claim 9, wherein the long diameter of the electromagnetic loss structures and the space between the electromagnetic loss structures have a relation of 0.1≤N1/N2<1.

12. The electromagnetic loss composite structure according to claim 9, wherein each of the electromagnetic loss structures is a hole penetrating through the magnetic oxide film body or a blind hole accessed in the magnetic oxide film body.

13. The electromagnetic loss composite structure according to claim 12, wherein the hole is circular, elliptic or rectangular.

14. The electromagnetic loss composite structure according to claim 12, wherein the blind hole is a cylindrical blind hole, a hemispherical blind hole, a semi-elliptical cylindrical blind hole or a square cylindrical blind hole.

15. The electromagnetic loss composite structure according to claim 9, wherein the first electromagnetic loss film and the second electromagnetic loss film correspond to different magnetic response frequencies.

16. The electromagnetic loss composite structure according to claim 9, wherein the electromagnetic loss structures in the first electromagnetic loss film and the second electromagnetic loss film are different in shape.

17. The electromagnetic loss composite structure according to claim 9, wherein the electromagnetic loss structures in the first electromagnetic loss film and the second electromagnetic loss film are different in long diameter or space.

18. The electromagnetic loss composite structure according to claim 17, wherein when the electromagnetic loss structures in the first electromagnetic loss film and the second electromagnetic loss film are different in long diameter, the larger long diameter is defined as R, and the smaller long diameter is defined as R1; R is defined as N1x light velocity/FR, and 0.005≤N1≤1; and R1 is defined as N1xN3x light velocity/FR, and 0.1≤N3≤1.
